(19) United States
(12) Patent Application Publication
(10) Pub. No.: US 2026/0151803 A1
(43) Pub. Date: Jun. 4, 2026

(54) CLEANING FIXTURE FOR SHOWERHEAD ASSEMBLIES

(71) Applicant: ASM IP Holding B.V., Almere (NL)

(72) Inventors: Dinkar Nandwana, Chandler, AZ (US); Allen D'Ambra, Phoenix, AZ (US); Dinh Tran, Tempe, AZ (US); Ankit Kimtee, Phoenix, AZ (US); Eric Shero, Phoenix, AZ (US)

(21) Appl. No.: 19/459,153

(22) Filed: Jan. 26, 2026

Related U.S. Application Data
(63) Continuation of application No. 17/537,567, filed on Nov. 30, 2021, now Pat. No. 12,564,871.
(60) Provisional application No. 63/120,618, filed on Dec. 2, 2020.

(51) Int. Cl. B08B 9/027; B08B 3/08; B08B 9/02; C23C 16/44; C23C 16/455; H01J 37/32

(52) U.S. Cl. CPC B08B 9/027; B08B 3/08; B08B 9/021; B08B 2209/027; C23C 16/4405; C23C 16/4407; C23C 16/45565; H01J 37/3244; H01J 37/32853

(57) ABSTRACT

Cleaning fixtures for cleaning a showerhead assembly are disclosure. The cleaning fixtures include: a fixture body incorporating three or more cavities, each cavity being separate from an adjacent cavity by a partition, and a number of channels associated with each cavity for fluidly connecting the cavities with an upper surface of the fixture body.

### CROSS-REFERENCE TO RELATED APPLICATIONS

This application is a continuation of U.S. application Ser. No. 17/537,567, filed Nov. 30, 2021 and entitled “CLEANING FIXTURE FOR SHOWERHEAD ASSEMBLIES,” which is a nonprovisional of, and claims priority to and the benefit of, U.S. Provisional Patent Application No. 63/120,618 , filed Dec. 2, 2020 and entitled “CLEANING FIXTURE FOR SHOWERHEAD ASSEMBLIES,” which are hereby incorporated by reference herein.

### FIELD OF INVENTION

The present disclosure relates generally to cleaning fixtures for cleaning a showerhead assembly that can be used in a vapor distribution assembly.

### BACKGROUND OF THE DISCLOSURE

Vapor-phase reactors, such as chemical vapor deposition (CVD), plasma-enhanced CVD (PECVD), atomic layer deposition (ALD), and the like can be used for a variety of applications, including depositing and etching materials on a substrate surface. For example, vapor-phase reactors can be used to deposit and/or etch layers on a substrate to form semiconductor devices, flat panel display devices, photovoltaic devices, microelectromechanical systems (MEMS), and the like.

A typical vapor-phase reactor system includes a reactor including, a reaction chamber, one or more precursor vapor sources fluidly coupled to the reaction chamber, one or more carrier or purge gas sources fluidly coupled to the reaction chamber, a vapor distribution system to deliver gases (e.g., the precursor vapor(s) and/or carrier or purge gas(es)) to a surface of a substrate, and an exhaust source fluidly coupled to the reaction chamber. The system also typically includes a susceptor to hold a substrate in place during processing. The susceptor can be configured to move up and down to receive a substrate and/or can rotate during substrate processing.

The vapor distribution system may include a showerhead assembly for distributing vapor(s) to a surface of the substrate. The showerhead assembly is typically located above the substrate. During substrate processing, vapor(s) flow from the showerhead assembly in a downward direction toward the substrate and then radially outward over the substrate.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In certain embodiments of the disclosure, a cleaning fixture configured for cleaning a showerhead assembly is provided. The cleaning fixture may include: a fixture body configured to be mounted to a showerhead assembly, the fixture body having an upper surface and a lower surface opposite the upper surface. The fixture body may include, an inner cavity disposed in the lower surface of the fixture body, the inner cavity being fluidly connected to the upper surface of the fixture body by one or more inner channels. The fixture body can also include, an outer cavity disposed in the lower surface of the fixture body, the outer cavity being fluidly connected to the upper surface of the fixture by one or more outer channels. In addition the fixture body may include, one or more intermediate cavities disposed in the lower surface of the fixture body and positioned between the inner cavity and the outer cavity, the one or more intermediate cavities being fluidly connected to the upper surface of the fixture by one or more intermediate channels. In certain embodiments the fixture body may also include, two or more partitions separating the one or more intermediate cavities from the inner cavity and the outer cavity.

In additional embodiments of the disclosure, a cleaning fixture for cleaning a showerhead assembly is provided including a fixture body configured to be mounted to a showerhead assembly. The fixture body may have an upper surface and a lower surface opposite the upper surface. The fixture body may also include, three or more cavities disposed in the lower surface of the fixture body, each cavity being separated from an adjacent cavity by a partition, and one or more channels associated with each cleaning cavity, the one or more channels fluidly connecting each of cavities to the upper surface of the fixture body.

Embodiments of the disclosure may also include, methods for cleaning a showerhead assembly. The cleaning methods may include, providing a showerhead plate with an undesirable material disposed on a surface of the showerhead plate, the undesirable film having a non-uniform average thickness. The cleaning methods can further include, mounting a cleaning fixture to the shower head plate, the cleaning fixture comprising a fixture body having an upper surface and a lower surface opposite the upper surface, the fixture body comprising, and three or more cavities disposed in the lower surface of the fixture body, each cavity being separated from an adjacent cavity by a partition, as well as one or more channels associated with each cavity, the one or more channels fluidly connecting each of cavities to the upper surface of the fixture body, and at least three independent conduits, each independent conduit connected to the one or more channels associated with each cavity. The cleaning methods can also include, providing a reservoir configured for retaining a cleaning chemical, mounting the cleaning fixture and the showerhead plate to the reservoir using a mounting clamp, and regulating the flow of a cleaning chemical through the three or more cavities utilizing a flow controller configured for independently controlling the flow of the cleaning chemical through each one of the three or more cavities. The cleaning methods can also include, asymmetrically removing the undesirable material disposed on the surface of showerhead plate.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWING FIGURES

While the specification concludes with claims particularly pointing out and distinctly claiming what are regarded as embodiments of the invention, the advantages of embodiments of the disclosure may be more readily ascertained from the description of certain examples of the embodiments of the disclosure when read in conjunction with the accompanying drawings, in which:

FIG. 1 illustrates a simplified cross-sectional schematic diagram of an exemplary vapor distribution system;

FIG. 2A illustrates a simplified cross-sectional schematic diagram of a cleaning fixture according to the embodiments of the disclosure;

FIG. 2B illustrates a simplified plan view schematic diagram of a cleaning fixture according to the embodiments of the disclosure;

FIG. 3 illustrates a cross-sectional schematic diagram of a cleaning apparatus according to the embodiments of the disclosure;

FIG. 4 illustrates a cross-sectional schematic diagram of a cleaning apparatus according to the embodiments of the disclosure;

FIG. 5A illustrates a simplified diagram of an exemplary flow controller and associated conduits employed for cleaning a showerhead assembly according to the embodiments of the disclosure;

FIG. 5B illustrates an additional simplified diagram of an exemplary flow controller and associated conduits employed for cleaning a showerhead assembly according to the embodiments of the disclosure; and

FIG. 5C illustrates an additional simplified diagram of an exemplary flow controller and associated conduits employed for cleaning a showerhead assembly according to the embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

The illustrations presented herein are not meant to be actual views of any particular material, structure, or device, but are merely idealized representations that are used to describe embodiments of the disclosure.

In the specification, it will be understood that the term “on” or “over” may be used to describe a relative location relationship. Another element or layer may be directly on the mentioned layer, or another layer (an intermediate layer) or element may be intervened therebetween, or a layer may be disposed on a mentioned layer but not completely cover a surface of the mentioned layer. Therefore, unless the term “directly” is separately used, the term “on” or “over” will be construed to be a relative concept. Similarly to this, it will be understood the term “under”, “underlying”, or “below” will be construed to be relative concepts.

The present disclosure includes cleaning fixtures for cleaning a showerhead assembly. In addition, the present disclosure includes cleaning apparatus configured for cleaning a showerhead plate of a showerhead assembly. Also, the present disclosure includes methods for cleaning a showerhead assembly.

Semiconductor processing apparatus may utilize reactor components including a multitude of apertures or orifices. For example, a semiconductor processing tool may utilize a showerhead assembly to distribute vapor phase reactants, carrier gases, purge gases, carrier gases, etc., into a reaction chamber associated with a semiconductor processing apparatus.

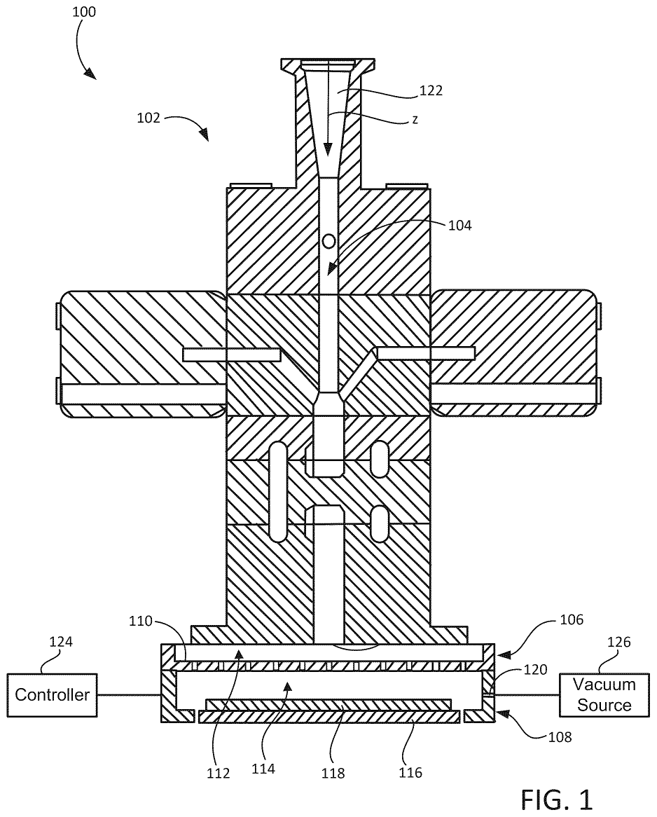

For example, FIG. 1 illustrates an example vapor distribution system which employs a showerhead assembly. In particular, FIG. 1 illustrates an exemplary semiconductor processing apparatus 100, which is also shown and described in connection with FIG. 8B of U.S. Patent Publication No. US 20170350011, the entire contents of which are incorporated by reference herein in their entirety and for all purposes. A manifold 102 is part of the overall semiconductor processing apparatus 100. The manifold 102 can include a bore 104 that injects vapor downwards towards a dispersion device comprising a showerhead assembly 106. It is understood that the manifold 102 can include multiple blocks connected together, as illustrated, or can comprise one unitary body. The manifold 102 can be connected upstream of a reaction chamber 108. In particular, an outlet of the bore 104 can communicate with a vapor dispersion mechanism, such as, a showerhead assembly 106, for example.

The showerhead assembly 106 includes a showerhead plate 110 that defines a showerhead plenum 112 or chamber above the showerhead plate 110. The showerhead assembly 106 communicates vapors from the manifold 102 to a reaction space 114 below the showerhead assembly 106. The reaction chamber 108 includes a substrate support 116 configured to support a substrate 118 (e.g., a semiconductor wafer) in the reaction space 114. The reaction chamber 108 also includes an exhaust opening 120 connected to a vacuum source 126. While shown with a single-wafer, the skilled artisan will appreciate that the manifold 102 can also be connected to other types of reaction chambers with other types of injectors, e.g., batch or furnace type, horizontal or cross-flow reactor, cluster reactors, etc.

The manifold 102 can inject multiple reactants such as a first reactant vapor phase reactant and a second reactant vapor phase reactant, either simultaneously to induce mixing, or sequentially to cycle between reactants. During some processes, a purge gas can be injected from the bore 104 to the showerhead assembly 106 in order to purge the first vapor phase reactant so that the first vapor phase reactant does not contaminate or mix with the subsequently-injected second vapor phase reactant. Similarly, after the deposition of the second vapor phase reactant and before deposition of another reactant (e.g., the first vapor phase reactant or a different reactant vapor), an additional purge step takes place in which inactive gas is delivered downwardly through an inlet 122 to the showerhead assembly 106 and reaction chamber 108. Although the embodiments disclosed herein are described in connection with the semiconductor processing apparatus 100 and particularly the showerhead assembly 106 of FIG. 1, it should be appreciated that the embodiments of the cleaning fixture described herein may be used with any suitable component comprising a plurality of apertures or orifices, which can be installed in any suitable type of semiconductor processing apparatus or system.

The semiconductor processing apparatus 100 may also include at least one controller 124, including processor(s) and memory with programming for controlling various components of the semiconductor processing apparatus 100. While shown schematically as connected to the reaction chamber 108, the skilled artisan will appreciate that the controller 124 communicates with various components of the reactor, such as vapor control valves, heating systems, gate valves, robot wafer carriers, etc., to carry out deposition processes. In operation, the controller 124 can arrange for a substrate 118 (such as a semiconductor wafer) to be loaded onto the substrate support 116, and for the reaction chamber 108 to be closed, purged and typically pumped down in readiness for deposition processes, particularly atomic layer deposition (ALD). The controller 124 can further be configured to control the sequence of deposition. For example, the controller 124 can send control instructions to reactant valve(s) to cause the reactant valve(s) to open and supply reactant vapor to the manifold 102. The controller 124 can also send control instructions to inactive gas valve(s) to cause the inactive gas valve(s) to open and supply inactive purge gas to the manifold 102. The controller 124 can be configured to control other aspects of the processes as well.

The semiconductor processing apparatus 100 of FIG. 1 may comprise a deposition apparatus configured for the deposition of one or more films onto the substrate 118 disposed within the reaction chamber 108. During such exemplary deposition processes, an undesirable material may be formed on one or more surfaces of the showerhead plate 110. Over an extended period of time and/or the deposition of multiple/thick films, this undesirable material disposed on the surfaces of showerhead plate 110 may impact the performance of the semiconductor processing apparatus 100. For example, the undesirable material may contribute to unwanted particles and debris in the reaction chamber which may in result a loss of device yield, for example. In addition, the showerhead plate 110 comprises a plurality of apertures configured for distributing vapor into the reaction space and as the undesirable material increases in thickness the dimensions of these showerhead plate apertures may decrease, which may eventually result in a blockage of one or more of the apertures, for example.

As a result of the unwanted effects of the undesirable material disposed on the surfaces of the showerhead plate, the showerhead assembly may be periodically disassembled and the showerhead plate removed from the semiconductor process apparatus. Once removed the showerhead plate may be subjected to maintenance routines to remove the undesirable material thereby restoring the showerhead plate to full functionality while also increasing the lifetime of the showerhead plate. For example, the showerhead plate may be removed from the semiconductor process apparatus and placed into a reservoir containing a cleaning chemical selected to remove the unwanted material without damaging, or significantly damaging, the showerhead plate. However, such a cleaning process commonly removes the undesirable material at a uniform rate. For example, the showerhead plate may be submerged in a liquid etchant which will uniformly etch the undesirable material. However, the undesirable material disposed on the surfaces of showerhead plate may have a non-uniform thickness, i.e., the average thickness of the undesirable material may differ at different location on the showerhead plate. In such instances wherein the undesirable material has a non-uniform thickness, the uniform removal of the undesirable material may be detrimental to the showerhead plate as over etching, to remove thicker portions of the desirable material, may result in unwanted damage to the showerhead plate, whereas under etching, to remove only the thinner portions of the undesirable material may result in areas of the unwanted material remaining on the showerhead plate. Therefore cleaning fixtures, cleaning apparatus, and cleaning methods are desirable for asymmetrically removing an undesirable material disposed on the surface of a showerhead plate thereby extending the working lifetime of both a showerhead assembly and the associated semiconductor processing apparatus.

Therefore, certain embodiments of the disclosure may include a cleaning fixture configured for cleaning a showerhead assembly comprising, a fixture body configured to be mounted to the showerhead assembly, the fixture body having an upper surface and a lower surface opposite the upper surface. In certain embodiments, the fixture body may comprise, an inner cavity disposed in the lower surface of the fixture body, the inner cavity being fluidly connected to the upper surface of the fixture body by one or more inner channels. In addition, in certain embodiments, the fixture body may include an outer cavity disposed in the lower surface of the fixture body, the outer cavity being fluidly connected to the upper surface of the fixture by one or more outer channels. In some embodiments, the fixture body may also include one or more intermediate cavities disposed in the lower surface of the fixture body and positioned between the inner cavity and the outer cavity, the one or more intermediate cavities being fluidly connected to the upper surface of the fixture by one or more intermediate channels. In addition, in certain embodiments, the fixture body may include two or more partitions separating the one or more intermediate cavities from the inner cavity and the outer cavity.

In certain embodiments of the disclosure, a cleaning fixture may be mounted to a showerhead assembly, and particular to a showerhead plate comprising a plurality of apertures. The cleaning fixture may comprise a number of cavities disposed in a lower surface of the cleaning fixture body, each cavity being in fluid communication with a flow controller. The cleaning fixture, with the showerhead plate mounted there, may be placed in a reservoir containing a cleaning chemical, wherein the cleaning chemical may contact one of more surfaces of the showerhead plate.

In some embodiments, the flow controller may be employed to draw the cleaning chemical through the plurality of apertures with a regulated flow, wherein the regulation of the flow may include but is not limited, the period of flow time of the cleaning chemical, and/or the flow rate of the cleaning chemical. In some embodiments, the flow controller may be configured to regulate the flow of the cleaning chemical differently through a first region of the plurality of apertures and a second region of the plurality of apertures. As non-limiting example, the flow controller may flow the cleaning chemical through a first region of the plurality of apertures for a longer time period than through a second region of the plurality of apertures. Therefore the cleaning chemical will contact different regions of the plurality of apertures for different time periods, thereby removing different amounts of the undesirable material from the surfaces of the showerhead plate, in other words the undesirable material having a non-uniform average thickness disposed on the surfaces of the showerhead plate may be asymmetrically removed from the showerhead plate employing the embodiments of the disclosure.

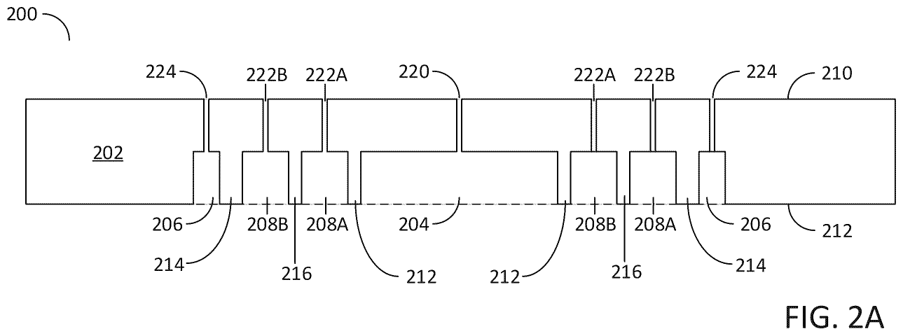

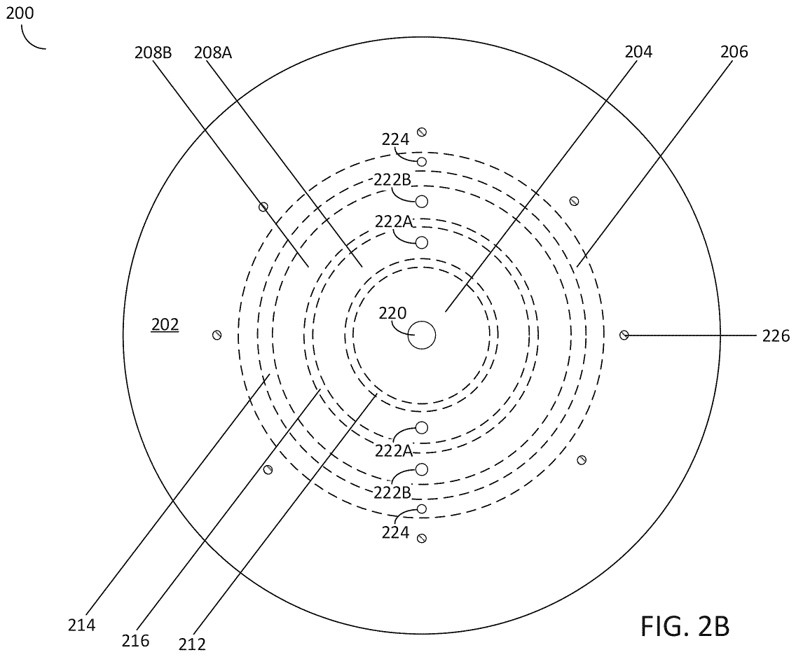

In more detail, FIG. 2A illustrates a cross sectional view of an embodiment of a cleaning fixture 200 for cleaning a showerhead assembly such as, for example, the showerhead assembly 106 of FIG. 1 and FIG. 2B illustrates a simplified plan view schematic diagram of a cleaning fixture according to the embodiments of the disclosure.

FIG. 2A illustrates an exemplary cleaning fixture 200 which may include a fixture body 202 (which can comprise, for example, a cylindrical bulk material) with an inner cavity 204, and an outer cavity 206, and one or more intermediate cavities 208A, 208B positioned between the inner cavity 204 and the outer cavity 206. The fixture body 202 can have an upper surface 210 and a lower surface 212 opposite the upper surface 210. The inner cavity 204, the outer cavity 206, and the one or more intermediate cavities 208A, 208B can be distinct cavities that are not fluidly connected.

For example, as shown in FIG. 2A, the inner cavity 204 can be separated from the one or more intermediate cavities 205A, 205B, by an inner partition 212. The inner partition 212 can comprise a portion of the fixture body 202, for example, a projection that extends downwardly from the fixture body between the inner cavity and the adjacent intermediate cavities. Further, the inner cavity 204, the one or more intermediate cavities 208A, 208B, and the outer cavity 206 can be exposed at (or can open to) the lower surface 212 of the fixture body 202.

In the embodiments of FIGS. 2A-2B, the one or more intermediate cavities 208A, 208B can at least partially surround the inner cavity 204. For the example, the one or more intermediate cavities 208A, 208B can at least partially surround the inner cavity 204. In certain embodiments, the one or more intermediate cavities 208A, 208B, can comprise annular shaped cavities that surround (e.g., completely surround) the inner cavity 204. In other embodiments, the one or more intermediate cavities may only partially surround the inner cavity 204.

In addition, in certain embodiments, the outer cavity 206 can at least partially surround the one or more intermediate cavities 208A, 208B. For the example, the outer cavity 206 can at least partially surround the one or more intermediate cavities 208A, 208B. For example, the outer cavity 206 can comprise an annular shaped cavity that surrounds (e.g., completely surround) the one or more intermediate inner cavities 206A, 206B. In other embodiments, the outer cavity 206 may only partially surround the one or more intermediate cavities 208A, 208B.

As shown in FIG. 2A, the outer cavity 206 can be separated from the one or more intermediate cavities 208A, 208B, by an outer partition 214. The outer partition 214 can comprise a portion of the fixture body 202, for example, a projection that extends downwardly from the fixture body between the outer cavity 206 and the adjacent intermediate cavities 208B, 208A. Additionally, one or more intermediate partitions can separate the one or more intermediate cavities from one other, such as, for example, intermediate partition 216 of FIG. 2A.

In certain embodiments, one or more inner channels 220 can be in fluid connection with the inner cavity 204. As show in FIG. 2A, an inner channel 220 can extend upwardly from the inner cavity 204 to the upper surface 210 of the fixture body 202. While a single inner channel 220 is illustrated in the exemplary cleaning fixture 200 of FIGS. 2A-2B, there may be any suitable number of inner channels 220.

The inner channel(s) 220 can be sized and arranged to flow a cleaning chemical through the inner cavity 204. The dimensions of the inner channels may depend on the size and dimensions of the showerhead assembly to be cleaned.

In certain embodiments, one or more intermediate channels can be in fluid connection with each of the one or more intermediate cavities 208A, 208B. As show in FIG. 2A, the intermediate channels 222A, 222B can extend upwardly from the intermediate cavities 208A, 208B to the upper surface 210 of the fixture body 202. While FIG. 2B illustrates a two intermediate channels associated with each intermediate cavity there may be any suitable number of intermediate channels in fluid communication with each of the intermediate cavities.

The one or more intermediate channels 222A, 222B can be sized and arranged to flow a cleaning chemical through the intermediate cavities 208A, 2080B. The dimensions of the intermediate channels may depend on the size and dimensions of the showerhead assembly to be cleaned.

In certain embodiments, one or more outer channels 224 may be connected to the outer cavity 206. For example, as shown in FIG. 2A, the one or more outer channels 224 can extend upwardly from the outer cavity 206 to the upper surface 210 of the fixture body 202. While two outer channels 224 are illustrated in FIG. 2B, there may be more than two outer channels. There may also be only one outer channels connected to the outer cavity 204.

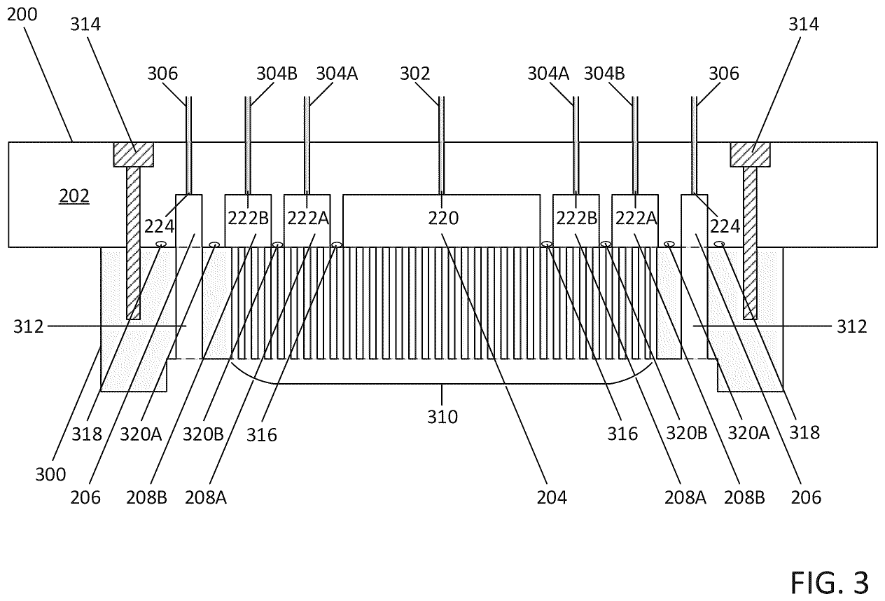

The major lateral dimension of the inner channels, intermediate channels, and the outer channels, may be adjusted with respect to one another depending on the amount of cleaning that is required for the inner apertures of a showerhead plate and the exhaust holes of a showerhead plate (described in further detail in connection with FIG. 3).

In some embodiments, the inner cavity 204 may comprise a cylindrical cavity (e.g., with an elliptical or circular profile as seen from a bottom plan view, as illustrated in FIG. 2B). The one or more intermediate channels 208A, 208B may include annular shaped (e.g., circular shaped or elliptical racetrack shaped) which surround the inner cavity. In addition, the outer cavity 206 may include an annular shape (e.g., a circular shape or an elliptical racetrack shape) which surrounds the both the intermediate cavities and the inner cavity.

In some embodiments the inner cavity 204 and the one or more intermediate cavities 208A, 208B may be divided into separate cavities which connect to separate inner apertures of a showerhead plate. Further, the outer cavity 206 may be divided into separate cavities which connect to separate exhaust holes disposed in the showerhead plate.

In some embodiments, the cleaning fixture 202 may be made out of a material softer than the material of a showerhead assembly. For example,, the cleaning fixture body 202 may be fabricated from materials including polymer(s) or plastic(s), such as, for example, polypropylene, or polyoxymethylene. In other embodiments, the fixture body 202 may be fabricated from materials including metal(s) or metal alloy(s), such as, for example, stainless steel, or aluminum. A softer material may allow the cleaning fixture 200 to avoid damaging a showerhead assembly when the two are mounted together. In some embodiments, the cleaning fixture may be fabricated from one or more materials which are etch resistant, i.e., resistant to attack from a corrosive cleaning chemical. For example, in certain embodiments, a cleaning chemical utilized to the remove undesirable material from the surfaces of a showerhead plate may be corrosive and in such embodiments the cleaning fixture 200 may be fabricated from one or more etch resistant material, such as, polyoxymethylene, for example. In such embodiments, at least the portion of the cleaning fixture in direct contact with the corrosive cleaning chemical should be fabricated from corrosion resistant materials.

FIG. 2B illustrates a simplified plan view of the cleaning fixture 200 of FIG. 2A and shares reference numbers with FIG. 2A and the description of the shared reference number is applicable for FIG. 2B. The inner cavity 204, the intermediate cavities 208A, 208B, and the outer cavity 206 are illustrated by the dashed lines in FIG. 2B for ease of illustration. As illustrate in FIG. 2B, the inner channel 220, the intermediate channels 222A, 222B, and the outer channels 224, may have round (e.g., circular) cross sectional shape. The cleaning fixture 200 may also include holes 226 which may be used for fixing a showerhead assembly to the cleaning fixture 200 by connectors or screws (as shown in FIG. 3). The exemplary cleaning fixture 200 as illustrated in FIGS. 2A and 2B may be connected to a showerhead plate of a showerhead assembly as illustrated and described with reference to FIG. 3.

FIG. 3 illustrates the cleaning fixture 200 of FIG. 2A and FIG. 2B mounted to a showerhead plate 300 of a showerhead assembly. Details of the cleaning fixture 200 are described in connection with FIGS. 2A and 2B and are not repeated. The one or more inner channels 220 are connected to an inner conduit 302 which is configured to flow a cleaning chemical through the inner cavity 204 and the one or more inner channels 220. The one or more intermediate channels 222A, 222B, associated with each of the intermediate cavities 208A, 208B, are connected to one or more intermediate conduits 304A, 304B, which are configured for flowing a cleaning chemical through the intermediate cavities 208A, 208B, and the one or more intermediate channels 222A, 222B. The one or more outer channels 224 are connected to an outer conduit 306 which is configured to flow a cleaning chemical into the outer cavity 206 and the one or more outer channels 224.

In certain embodiments, the inner conduit 302, the one or more intermediate conduits 304A, 304B, and the outer conduit 306, are independent and isolated from one another.

The showerhead plate 300 includes both a plurality of inner apertures 310 and exhaust holes 312. The exhaust holes 312 are positioned to surround the inner apertures 310 and are located radially outward from the inner apertures 310 with respect to the center of the showerhead plate 300. The inner apertures 310 may be substantially cylindrical holes or they may have flared inputs and/or outputs. The inner apertures 310 may have any suitable profile. Similarly, the outer exhaust holes 312 may be substantially cylindrical holes or they may have flared inputs and/or outputs. The outer exhaust holes 312 may have any suitable profile. In certain embodiments, each of the plurality of inner apertures 310 are substantially smaller than each of the exhaust holes 312. For example, when the inner apertures 310 and exhaust holes 312 are substantially cylindrical holes, the diameter of the exhaust holes 312 may be larger than the diameter of the inner apertures 306.

Further, when the inner apertures 312 may have a flared input and/or output and the exhaust holes 312 may have a flared input and/or output, each of the inner apertures 310 and each of the exhaust holes 312 may include a cylindrical middle portion. The cylindrical middle portion of the exhaust holes 312 can be larger than the cylindrical middle portion of the inner apertures 310. When the showerhead plate 302 and showerhead assembly are used in a semiconductor processing apparatus, gas (e.g., reactant and/or inactive gases) can be delivered to the reaction chamber through the inner apertures 310. The gases can be removed or exhausted from the reaction chamber through the exhaust holes 312.

In certain embodiments of the disclosure, the cleaning fixture 200 can be mounted to the showerhead plate 300 such that the inner apertures 310 are in fluid communication with the inner cavity 204 and the one or more intermediate cavities 208A, 208B. In certain embodiments, the exhaust holes 304 are in fluid communication with the outer cavity 204. As illustrated in FIG. 3, the cleaning fixture 200 can be mounted to the showerhead 302 by one or more connectors 314 (e.g., one or more screws, bolts, or other suitable fastener). The cleaning fixture 200 may be mounted to the showerhead plate 300 by other fasteners, such as a clamp, for example. By providing separate and independent fluid access to different regions of the inner apertures 310 of the showerhead plate (via the inner cavity 204 and the one or more intermediate cavities 208A, 208B) and separate and independent fluid access to the exhaust holes 314 (via the outer cavity 206), the showerhead plate 300 may be asymmetrically cleaned with a cleaning chemical. In other words, one or more different chemical cleaning processes may be applied to different regions of the showerhead plate 300 in fluid communication with the various cavities 204, 206, and 208A-B, of the cleaning fixture 200.

In certain embodiments of the disclosure, one or more gaskets may be positioned between the cleaning fixture 200 and the showerhead plate 300. An inner gasket 316 can be positioned between the cleaning fixture 200 and the showerhead plate 300 and surrounds the inner cavity 204 in a direction parallel to the extending direction of the cleaning fixture. When the cleaning fixture 200 is mounted to the showerhead plate 300, the inner gasket 316 keeps the cleaning chemical flowing through the inner cavity 204 from entering the intermediate cavities, the outer cavity, and the one or more exhaust holes.

In addition, an outer gasket 318 can be position between the cleaning fixture 200 and the showerhead plate 300 and surrounds the one or more intermediate cavities 208A, 208B, in a direction parallel to the extending direction of the cleaning fixture. When the cleaning fixture 200 is mounted to the showerhead plate 300, the outer gasket 318 seals the cleaning chemical from exiting the showerhead plate 300 and the cleaning fixture 200.

Further intermediate gaskets 320A, 320B, can be place between the cleaning fixture 200 and the showerhead plate 300 to isolation the intermediate cavities from one another while also isolating the one or more intermediate cavities from the inner cavity 204 and the outer cavity 206.

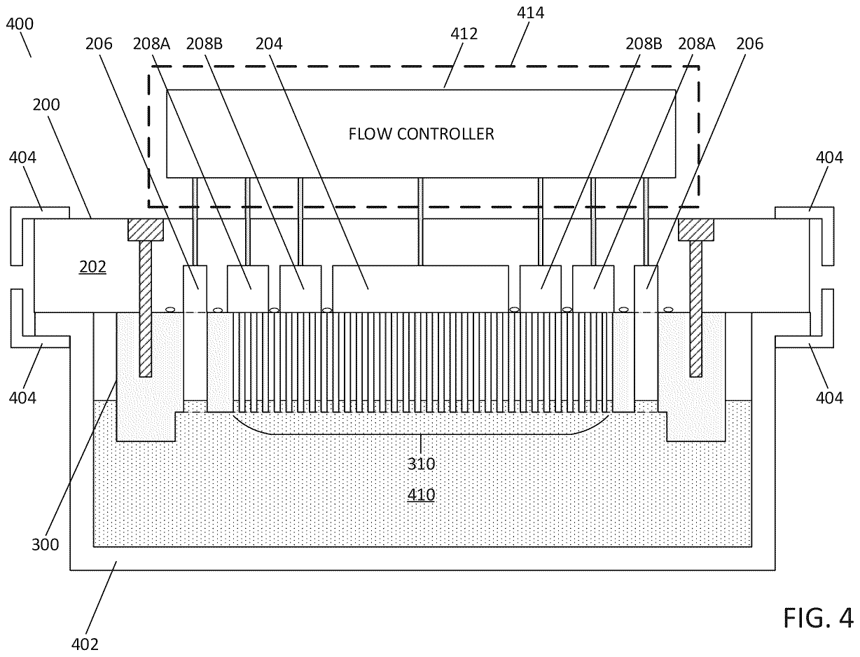

FIG. 4 illustrates an exemplary cleaning apparatus 400 for cleaning a showerhead assembly. The cleaning apparatus 400 includes the cleaning fixture 200 mounted on the showerhead plate 300 of FIG. 3. The features of FIG. 3 are not repeated here. In certain embodiments, a reservoir 402 is positioned below the cleaning fixture 200, the cleaning fixture being mounted on the showerhead plate 300. The reservoir 402 may be secured to the cleaning fixture 200, and the showerhead plate 300 mounted thereon, by one or more clamps 404. The reservoir 402 may also be secured to the cleaning fixture 200 and/or the showerhead plate 300 through screw(s) or bolt(s), or the cleaning fixture 200, mounted to the showerhead plate 300, may be placed above the reservoir 400 unsecured, for example, when utilizing non-hazardous cleaning chemicals.

In certain embodiments of the present disclosure, the reservoir 402 may be configured for retaining a cleaning chemical 410. In some embodiments, the cleaning chemical may comprise a cleaning liquid, such as, a liquid acid (e.g., nitric acid, or hydrofluoric acid).

In certain embodiments, the cleaning chemical may comprise a cleaning gas, such as, an etchant gas (e.g., hydrochloric (HCl) acid vapor, nitrogen trifluoride (NF₃), chlorine trifluoride (ClF₃), or molecular fluorine (F₂)). In a particular embodiment of the disclosure, the cleaning chemical 410 may comprise water vapor (e.g., steam generated from heating de-ionized water). When utilizing a cleaning gas, such as, water vapor, or a etchant gas, the exemplary cleaning apparatus 400 and particular the reservoir 402 may include additional features (not illustrated) to safely collect and retain waste cleaning gas.

In certain embodiments, the cleaning chemical may comprise a cleaning plasma (i.e., an excited gas (e.g., NF₃) including, excited species, radicals, and ions). When utilizing a cleaning plasma the exemplary apparatus 400 and particular the reservoir 402 may include additional features (not illustrated) to safely collect and retain waste reactants and by-products produced by the reaction between the plasma and the undesirable material.

In certain embodiments, the cleaning chemical 410 may be selected such that a undesirable material disposed on the showerhead plate 300 is at least substantially removed without significantly etching the showerhead plate itself, i.e., the cleaning chemical selectively removes the undesirable material relative to the showerhead plate. In particular embodiments, the reservoir 402 may also include additional components (not illustrated) for generating the cleaning chemical, such as, for example, a heating system for generating steam from de-ionized water, or a plasma generator (e.g., remote plasma generator) for generating a cleaning plasma.

In certain embodiments, the cleaning apparatus 400 may further comprise a flow controller 412 configured for regulating the flow of a cleaning chemical through the inner cavity, the one or more intermediate cavities, and the outer cavity. In some embodiments the flow controller 412 may be configured for independently regulating the flow of a cleaning chemical through each one of the inner cavity 204, the one or more intermediate cavities 208A, 208B, and the outer cavity 206. In some embodiments, the flow controller 412 may be configured for independently controlling the flow rate of a cleaning chemical through each one of the inner cavity 204, the one or more intermediate cavities 208A, 208B, and the outer cavity 206. In some embodiments, the flow controller may be configured for independently controlling the period of flow time of the cleaning chemical flow through each one of the inner cavity 204, the one or more intermediate cavities 208A, 208B, and the outer cavity 206.

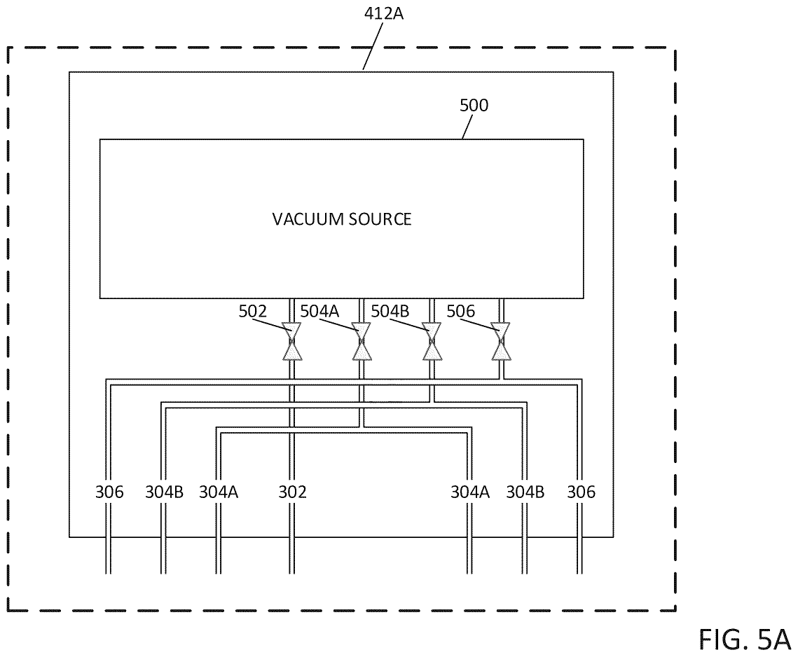

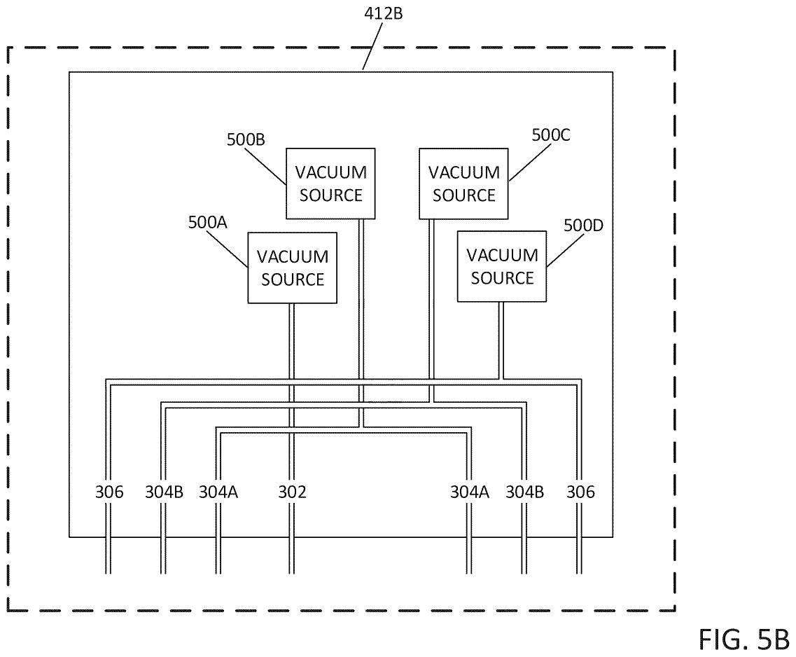

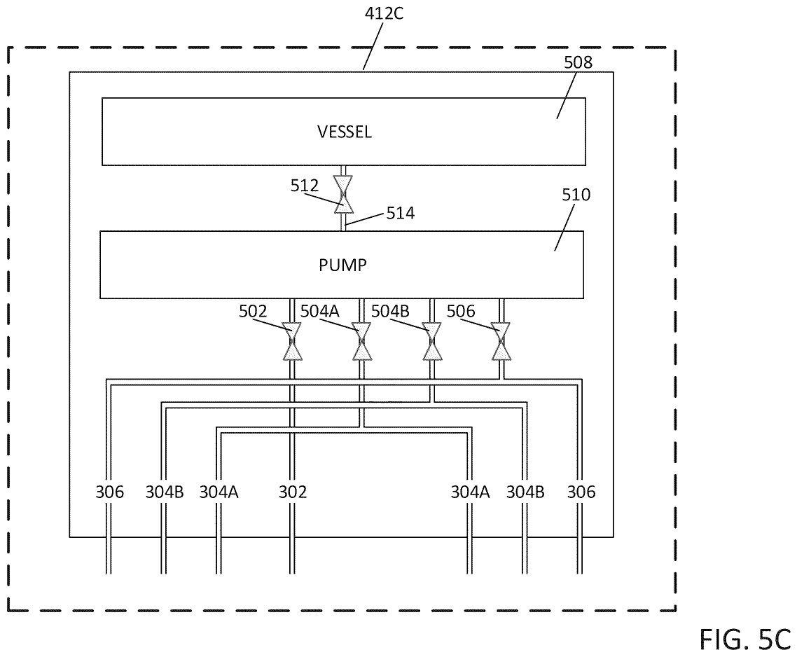

The region of the cleaning apparatus 400 enclosed by the dashed box 414 is illustrated and described with reference with FIG. 5A and FIG. 5B, which provide simplified exemplary embodiments of the flow controller 414 and the arrangement of the associated conduits (e.g., inner, intermediate, and outer conduits as illustrated and described with reference to FIG. 3) which are fluidically connected to the flow controller 412. It should be noted that the exemplary embodiments of the flow controller and the arrangement of the associated conduits are shown in a simplified form and that additional conduits, valves, flow controllers, flow sensors, reservoirs, etc., may be employed in addition to the components illustrated in FIG. 5A and FIG. 5B.

FIG. 5A illustrates an exemplary flow controller 412A and associated conduits 302, 304A, 304B, and 306. In some embodiments, a common vacuum source may be connected to the inner conduit, the one or more intermediate conduits, and the outer conduit; and at least one flow regulator may be connected to at least one of the inner conduit, the one or more intermediate conduits, and the outer conduit. As illustrated in FIG. 5A, a common vacuum source 500, such as a vacuum pump, for example, may be fluidically connected to the inner conduit 302, the one or more intermediate conduits 304A, 304B, and the outer conduit 306. In addition, the flow controller 412 may comprise one or more flow regulators 502, 504A, 504B, 506, such as, one or more flow valves, which may be connected to at least one of the inner conduit 302, the intermediate conduits 304A, 304B, and the outer conduit 306.

The exemplary flow controller 412A, may independently regulate at least one of the flow rate and/or period of flow time of a cleaning chemical through the inner conduit 302, the one more intermediate conduits 304A, 304B, and the outer conduit 306, by use of the vacuum source 500 and the flow regulators 502, 504A, 504B, and 506, which in turn results in asymmetrical removal of an undesirable material disposed on a showerhead plate.

FIG. 5B illustrates an exemplary flow controller 412B and associated conduits 302, 304A, 304B, and 306. In some embodiments, at least one vacuum source may be connected to each one of the inner conduit, the one or more intermediate conduits, and the outer conduit. As illustrated in FIG. 5B, multiple vacuum sources (in this example four (4) vacuum sources) are employed, a single independent vacuum source being fluidically connected to each one of the inner conduit 302 (via vacuum source 502), the one or more intermediate conduits 304A, 304B (via vacuum source 504A, and 504B), and the outer conduit 306 (via the vacuum source 506).

The exemplary flow controller 412B, may independently regulate at least one of the flow rate and/or period of flow time of a cleaning chemical through the inner conduit 302, the one more intermediate conduits 304A, 304B, and the outer conduit 306, by use of the independently controlled vacuum sources 500A, 500B, 500C, and 500D, which in turn results in asymmetrical removal of an undesirable material disposed on a showerhead plate.

Alternative flow controller configurations and their associated conduits, reservoir(s), and ancillary components etc., may be envisioned and employed as part of the present disclosure.

For example, FIG. 5C illustrates an exemplary flow controller 412C and associated conduits 302, 304A, 304B, and 306. In this exemplary embodiment, a vessel 508 is configured for storing a cleaning chemical, such as, for example, a liquid etchant or a vapor etchant. The vessel 508 may also include additional components (not illustrated) for generating the cleaning chemical, such as, for example, a heating system for generating steam from de-ionized water, or a plasma generator (e.g., remote plasma generator) for generating a cleaning plasma.

A pump 510 can be fluidly connected to the vessel 508 and employed to transfer the cleaning chemical stored within the vessel 509 to the cleaning fixture via conduit 514 (between the vessel 508 and the pump 510) and the inner conduit 302, the intermediate conduits 304A, 304B, and the outer conduit 306 (between the pump 510 and the cleaning fixture). Although FIG. 5C illustrates the exemplary flow controller 412C with a single common pump 510 and a single vessel 508, it also envisioned that multiple pumps and/or multiple vessels may be employed to enable alternative/additional cleaning functionality, i.e., multiple cleaning chemistries, independent pumping control of cleaning chemistries, etc.

As illustrated in previous examples, the exemplary flow controller 412C may also comprise one or more flow regulators 502, 504A, 504B, 506 (e.g., flow valves) connected to the conduits for regulating flow of cleaning chemical from the vessel 508 to the cleaning fixture. An addition flow regulator 512 may be added to the conduit 514 fluidly connecting the vessel 502 to the pump 504.

The exemplary flow controller 412C, may independently regulate at least one of the flow rate and/or period of flow time of a cleaning chemical from the vessel 508 and through the inner conduit 302, the one more intermediate conduits 304A, 304B, and the outer conduit 306, by use of the pump 502 and the flow regulators 502, 504A, 504B, and 506, which in turn results in asymmetrical removal of an undesirable material disposed on a showerhead plate. In the embodiments described herein, the reservoir 402 or an additional vessel (not shown) may also be utilized for storing a flushing chemical which may be utilized to flush the cleaning fixture and the showerhead assembly after cleaning has been completed thereby removing any residual cleaning chemicals or cleaning by-products. For example, the reservoir 402 (or an additional vessel) may be refilled with de-ionized water which can flushed through the cleaning fixture and the showerhead plate mounted thereon (e.g., by either employing one or vacuum sources or one or more pumps).

The embodiments of the disclosure may also comprise methods for cleaning a showerhead assembly. In certain embodiments, methods of cleaning a showerhead assembly may comprise, providing a showerhead plate with an undesirable material disposed on a surface of the showerhead plate, the undesirable material having a non-uniform average thickness. The methods of cleaning may further comprise, mounting a cleaning fixture to the shower head plate, the cleaning fixture comprising a fixture body having an upper surface and a lower surface opposite the upper surface. In certain embodiment the cleaning method may further comprise, a fixture body including three or more cavities disposed in a lower surface of the fixture body, each cavity being separated from an adjacent cavity by a partition, and one or more channels associated with each cavity, the one or more channels fluidly connecting each of cavities to the upper surface of the fixture body, and at least three independent conduits, each independent conduit connected to the one or more channels associated with each cavity. The methods of cleaning a showerhead assembly may further comprise, providing a reservoir configured for retaining a cleaning chemical, and mounting the cleaning fixture and the showerhead plate to the reservoir using a mounting clamp. The methods of cleaning a showerhead assembly may further comprise, regulating the flow of a cleaning chemical through the three or more cavities utilizing a flow controller configured for independently controlling the flow of the cleaning chemical through each one of the three or more cavities, and asymmetrically removing the undesirable material disposed on the surface of showerhead plate.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combination of the elements described, may become apparent to those skilled in the art from the description. Such modifications and embodiments are also intended to fall within the scope of the appended claims.

What is claimed is:

1. A cleaning fixture configured for cleaning a showerhead assembly comprising:
a fixture body configured to be mounted to the showerhead assembly, the fixture body having an upper surface and a lower surface opposite the upper surface, the fixture body comprising:
an inner cavity open to the lower surface of the fixture body, the inner cavity being fluidly connected to the upper surface of the fixture body by one or more inner channels;
an outer cavity open to the lower surface of the fixture body, the outer cavity being fluidly connected to the upper surface of the fixture body by one or more outer channels; and
a partition separating the inner cavity and the outer cavity,
wherein the partition extends to the lower surface, and
wherein the outer cavity surrounds the inner cavity.

2. The cleaning fixture of claim 1, wherein the inner cavity comprises a cylindrical cavity.

3. The cleaning fixture of claim 1, wherein the outer cavity comprises an annular ring.

4. The cleaning fixture of claim 1, wherein the fixture body is fabricated from at least one of a polymer, a plastic, a metal, or a metal alloy.

5. The cleaning fixture of claim 1, wherein a cross-sectional area of the inner cavity is greater than a cross-sectional area of each of the one or more inner channels.

6. The cleaning fixture of claim 1, further comprising:
an inner conduit connected to the one or more inner channels; and
an outer conduit connected to the one or more outer channels,
wherein the inner conduit and the outer conduit are independent from one another.

7. A cleaning apparatus comprising:
the cleaning fixture of claim 6;
a showerhead plate comprising inner showerhead apertures and one or more showerhead exhaust holes, wherein the cleaning fixture is mounted to the showerhead plate by a connector such that the one or more inner channels are in fluid communication with the inner showerhead apertures and the one or more outer channels are in fluid communication with the one or more showerhead exhaust holes;
a reservoir configured for retaining a cleaning chemical; and
a mounting clamp configured for mounting the cleaning fixture and the showerhead plate to the reservoir.

8. The cleaning apparatus of claim 7, further comprising a flow controller configured for regulating a flow of the cleaning chemical through the inner cavity and the outer cavity.

9. The cleaning apparatus of claim 8, wherein the flow controller is configured for independently regulating the flow of the cleaning chemical through each one of the inner cavity and the outer cavity.

10. The cleaning apparatus of claim 9, wherein the flow controller is configured for independently controlling a flow rate of the cleaning chemical through each one of the inner cavity and the outer cavity.

11. The cleaning apparatus of claim 10, wherein the flow controller is configured for independently controlling a period of flow time of the cleaning chemical through each one of the inner cavity and the outer cavity.

12. The cleaning apparatus of claim 8, wherein the flow controller comprises:
a single common vacuum source connected to the inner conduit and the outer conduit; and
at least one flow regulator connected to at least one of the inner conduit and the outer conduit.

13. The cleaning apparatus of claim 8, wherein the flow controller comprises, at least one vacuum source connected to each one of the inner conduit and the outer conduit.

14. The cleaning apparatus of claim 7, wherein the cleaning chemical comprises a liquid etchant.

15. The cleaning apparatus of claim 7, wherein the showerhead plate comprises a metal or a metal alloy.

16. The cleaning apparatus of claim 7, further comprising an undesirable material disposed on a surface of the showerhead plate, the undesirable material having a non-uniform average thickness and comprising a material different from a metal or a metal alloy of the showerhead plate.

17. A method of cleaning a showerhead assembly comprising:
providing a showerhead plate with an undesirable material disposed on a surface of the showerhead plate;
mounting a cleaning fixture to the showerhead plate, the cleaning fixture comprising a fixture body having an upper surface and a lower surface opposite the upper surface, the fixture body comprising;
three or more cavities disposed in the lower surface of the fixture body, each cavity being separated from an adjacent cavity by a partition;
one or more channels associated with each cavity, the one or more channels fluidly connecting each of cavities to the upper surface of the fixture body; and
at least three independent conduits, each independent conduit connected to the one or more channels associated with each cavity,
wherein at least one of the three or more cavities surrounds another of the three or more cavities, and
wherein the partition extends to the lower surface;
providing a reservoir configured for retaining a cleaning chemical;
mounting the cleaning fixture and the showerhead plate to the reservoir using a mounting clamp;
regulating a flow of the cleaning chemical through the three or more cavities; and
removing the undesirable material disposed on the surface of the showerhead plate.

18. The method of claim 17, wherein the regulating the flow of the cleaning chemical comprises independently regulating the flow of the cleaning chemical through each of the three or more cavities.

19. The method of claim 18, wherein the independently regulating the flow of the cleaning chemical comprises independently controlling a flow rate of the cleaning chemical through each of the three or more cavities.

20. The method of claim 18, wherein the independently regulating the flow of the cleaning chemical comprises independently controlling a period of flow time of the cleaning chemical through each of the three or more cavities.
